(19) United States
(12) Patent Application Publication
(10) Pub. No.: US 2011/0180311 A1
(43) Pub. Date: Jul. 28, 2011

(54) SOLDER, ELECTRONIC PART, AND METHOD OF FABRICATING ELECTRONIC PART

(75) Inventors: TOSHIMASA TSUDA, Sayama-shi (JP); MITSUO HORI, Sakura-shi (JP)

(73) Assignee: NIHON DEMPA KOGYO CO., LTD., TOKYO (JP)

(21) Appl. No.: 13/009,445

(22) Filed: Jan. 19, 2011

(30) Foreign Application Priority Data
Jan. 22, 2010 (JP) 2010-012423

(51) Int. Cl. H05K 1/09; B23K 35/24; C22C 13/00; B23K 31/02; B23K 1/20

(52) U.S. Cl. 174/260; 148/24; 420/560; 228/180.21

(57) ABSTRACT

A solder material with favorable mechanical properties and high corrosion resistance is provided. The solder material is not apt to be melted in a re-heating process after the soldering process is performed. The solder material includes first solder powder, Cu powder, and a flux. The first solder powder contains Cu, Si, Ti, and Sn. Here, Cu accounts for 7 wt %˜9 wt %, Si accounts for 0.001 wt %˜0.05 wt %, Ti accounts for 0.001 wt %˜0.05 wt %, and the rest is Sn. The Cu powder is coated by Ag. The flux is mixed with the first solder powder and the Cu powder.

### CROSS-REFERENCE TO RELATED APPLICATION

This application claims the priority benefit of Japan application serial no. 2010-012423, filed on Jan. 22, 2010. The entirety of the above-mentioned patent application is hereby incorporated by reference herein and made a part of specification.

### BACKGROUND OF THE INVENTION

1. Field of the Invention

The invention relates to an electronic part in which a surface mount part is packaged on a wiring substrate (e.g., a printed wiring board (PWB)). More particularly, the invention relates to a solder material adapted to an electronic part in which a surface mount part is sealed, an electronic part having the solder material, and a method of fabricating an electronic part using the solder material.

2. Description of Related Art

The surface of a small-size electronic part (e.g., a ceramic capacitor, a surface acoustic wave (SAW) device chip, and so on) is packaged on a substrate, and said small-size electronic part is referred to as a surface mount part. When the surface mount part is packaged on a substrate (e.g., a printed wiring board (PWB)), the surface mount part is sometimes sealed in order to prevent moisture or rupture caused by delivery and is processed as an electronic part unit (hereinafter referred to as an electronic part). The sealing process includes following steps: providing a substrate with a thermal curable molding material and curing the molding material after the entire surface of the surface mount part is covered by the molding material. Here, epoxy resin serves as the main ingredient of the thermal curable molding material.

At present, the surface mount part is packaged on the substrate by performing a reflow process in most cases. The reflow process includes following steps. A cream solder material, i.e., a soldering paste or a cream solder, is aligned to patterns on the substrate in advance for print and dispensation. After the surface mount part is placed on the solder material, the substrate is moved into a heating furnace (i.e., the so-called reflow furnace). When the substrate passes the reflow furnace, the solder material on the substrate is melted, such that the surface mount part and the substrate are soldered. Thereby, a plurality of surface mount parts can be soldered to the same substrate by performing one single reflow process, and thus the surface mount parts can be densely placed on the substrate.

In a process of assembling an electronic product, e.g., a mobile phone, the electronic parts formed by packaging and sealing the surface mount parts as described above are packaged on the substrate. In consideration of the aforesaid advantages, the reflow process is often applied for packaging the electronic parts to assemble the electronic product.

However, during the reflow process, a soldering step is performed by applying the heat from the periphery of the substrate, and the heat is the same as the afore-mentioned heat used to melt the solder in the reflow furnace. Therefore, when the substrate that carries the electronic parts passes the furnace, the solder on the substrate is melted, and so is the solder in the electronic parts.

The solder in a melting state in the electronic part is described with reference to FIG. 6(a) to FIG. 6(c). FIG. 6(a) is an enlarged, vertical cross-sectional view illustrating the internal state of an electronic part before the electronic part is moved into a reflow furnace. Electrodes 32 located at two ends of the surface mount part 3A and electrodes (i.e., installation pads 22) formed on the substrate 21 are mounted by the solder material 41, such that the surface mount part 3A is fixed onto the substrate 21, and that the electrodes 32 and 22 are electrically connected. As shown in FIG. 6(a), the sealing material 51 seals the surface mount part 3A.

If the electronic part having said configuration is moved into the reflow furnace, the solder material 41 in the electronic part is heated and starts to melt. When the solder metal in a solid state is transformed to a liquid state, the volume of the metal is expanded. Hence, when the solder material 41 in the electronic part is melted and expanded, the expanded solder material 41 is likely to result in expansion of the interface between the surface mount part 3A or the substrate 21 and the sealing material 51, as shown in FIG. 6(b).

As a result, the melted solder material 41 is overflowed in the space among the expanded components, i.e., the electronic part 3A, the substrate 21, and the sealing material 51, which may cause breakdowns to the surface mount part 3A because of short circuit between the electrodes 32 of the surface mount part 3A.

As disclosed in JP patent publication no. 2003-154485, in order for the solder material not to melt again when electronic parts are packaged on machine, researches are directed to the composition of the solder material, so as to raise the temperature (i.e., a solidus temperature) at which the solder material starts to melt to 261° C. or more.

Besides, as disclosed in JP patent publication no. 2006-102769, the solder material refers to a Sn-3.0Ag-0.5Cu solder alloy which is extensively applied as a non-lead solder, for instance. In the solder alloy, Ag accounts for 3.0 wt %, Cu accounts for 0.5 wt %, and the rest is Sn. Besides, in the solder material, Cu powder coated by the Ag metal film is dispersed in the solder material, for instance.

Moreover, as disclosed in JP patent publication no. 2001-58287, the solder material includes Cu, Ti, Si, and Sn. Here, Cu accounts for 0.01 wt %˜6.0 wt %, Ti accounts for 0.001 wt %˜1.0 wt %, Si accounts for 0.001 wt %˜1.0%, and the rest is Sn. However, the JP patent publication no. 2001-58287 does not include the embodiments that are directed to the solder material, the melting temperature (i.e., the liquidus temperature) of the solder material, and the properties of the solder material.

### RELATED ART

### Patents and Patent Publications

Patent Publication 1: JP patent publication no. 2003-154485: claim 1
Patent Publication 2: JP patent publication no. 2006-102769: paragraph [0024]
Patent Publication 3: JP patent publication no. 2001-58287: claims 1, 5, 6, and 10

The melting temperature of the solder material as disclosed in JP patent publication no. 2003-154485 is higher than the melting temperature of the conventional solder material. Therefore, when the surface of the electronic part is packaged, the solder material is not apt to be melted, and the breakdowns caused by volume expansion of the solder material are less likely to occur. However, as long as the melting temperature reaches 261° C. or more, for instance, the reflow furnace may be excessively employed in the first reflow process, or the degradation of the electronic part may arise from heat.

Additionally, in the solder material disclosed in JP patent publication no. 2006-102769, the Cu powder having a melting temperature higher than that of the solder alloy is dispersed in the solder material, so as to reduce the proportion of the melted solder material and further restrain the volume expansion of the melted solder material. Besides, when the solder material is melted at the first time during the soldering process for mounting the surface mount part, Ag coated onto the Cu powder or Cu of the Cu powder is dispersed in the solder alloy. By increasing the liquidus temperature of the solder alloy, the solder material in the electronic part cannot be easily melted in the reflow process subsequently performed when the electronic part is packaged.

However, in areas where Ag or Cu is not fully dispersed, for instance, the solder material in the electronic part may still be melted. Moreover, on the condition that the proportion of the Cu powder in the solder material is insufficient, the volume expansion of the solder material cannot be sufficiently restrained, and thus further improvement is required.

### SUMMARY OF THE INVENTION

In view of the above, the invention provides a solder material that cannot be easily melted in a re-heating process after the soldering process is performed. The solder material has favorable mechanical properties or high corrosion resistance.

The solder material described in the embodiments of the invention is characterized in that the solder material includes:

first solder powder that contains Cu, Si, Ti, and Sn, wherein Cu accounts for 7 wt %˜9 wt %, Si accounts for 0.001 wt %˜0.05 wt %, Ti accounts for 0.001 wt %˜0.05 wt %, and the rest is Sn; Cu powder, coated by Ag; and

a flux, mixed with the first solder powder and the Cu powder.

The solder material is further characterized by the following:

(a) the Cu powder accounts for 10 wt %˜35 wt % of the total weight of the first solder powder and the Cu powder, and the rest is the first solder powder;

(b) the solder material further includes second solder powder that contains Ag, Cu, and Sn, wherein Ag accounts for 2.9 wt %˜3.1 wt %, Cu accounts for 0.4 wt %˜0.6 wt %, and the rest is Sn;

(c) in (b), the Cu powder accounts for 10 wt %˜35 wt % of the total weight of the first solder powder, the second solder powder, and the Cu powder, the second solder powder accounts for 0.1 wt %˜60 wt % of the total weight of the first solder powder, the second solder powder, and the Cu powder, and the rest is the first solder powder.

The invention further provides a solder material. The solder material is characterized in that the solder material includes a solder composition containing Cu, Si, Ti, and Sn, wherein Cu accounts for 7 wt %˜9 wt %, Si accounts for 0.001 wt %˜0.05 wt %, Ti accounts for 0.001 wt %˜0.05 wt %, and the rest is Sn.

The invention further provides an electronic part that is characterized in that a surface mount part is packaged on a wiring substrate by applying the aforesaid solder material.

The invention further provides an electronic part that is characterized in that a surface mount part is packaged on a wiring substrate by the aforesaid solder material and is sealed by applying a sealing material.

The invention further provides a method of fabricating an electronic part, characterized in that the method includes following steps:

providing electrodes of a wiring substrate with the aforesaid solder material;

placing a surface mount part on the solder material;

electrically connecting electrodes of the surface mount part to the electrodes of the wiring substrate by heating and melting the solder material; and

sealing the surface mount part by a sealing material.

### Technical Effects

The first solder powder described in an embodiment of the invention contains Cu, Si, Ti, and Sn. Here, Cu accounts for 7 wt %˜9 wt %, Si accounts for 0.001 wt %˜0.05 wt %, Ti accounts for 0.001 wt %˜0.05 wt %, and the rest is Sn. According to this embodiment, the first solder powder starts to melt at approximately 235° C. A surface mount part is packaged by applying the solder material having the first solder powder and is sealed to form an electronic part. Therefore, even though the frequently used Sn-3.0Ag-0.5Cu solder material having a solidus temperature at about 217° C. is applied to package said electronic part in a machine, the solder material in the electronic part cannot be easily melted. Since the solder material is not apt to be melted, and the breakdowns to the electronic part caused by the volume expansion of the solder material are less likely to occur.

Moreover, the first solder powder includes a trace of Si and a trace of Ti as addictives. Si improves flowability of the solder material during the soldering process and has a function of deoxidization for micronizing the crystalline structure of the solder. In addition, the individually added Si can reduce the tensile strength of the alloy on which the soldering process is performed. By contrast, Ti improves the density of the crystalline structure of the alloy after the soldering process is performed and thereby enhances the mechanical strength, heat resistance, and corrosion resistance. Besides, the individually added Ti leads to the rapid increase in the melting temperature, and thus dross (oxide) is generated in the crystalline structure and on the surface of the solder after the soldering process is performed. By adding Si and Ti to the first solder powder, Si and Ti can develop the merits and compensate the demerits. As such, the solder material that is suitable for performing a soldering process, has favorable mechanical strength, and is characterized by high heat resistance and high corrosion resistance can be obtained.

To make the above and other features and advantages of the invention more comprehensible, several embodiments accompanied with figures are detailed as follows.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1(a) to FIG. 1(d) illustrate a process of forming an electronic part by using a solder material described in an embodiment of the invention.

FIG. 2 illustrates exemplary distribution of temperature at which a reflow process is performed for mounting surface mount parts and the electronic part.

FIG. 3 is an enlarged view of a bonding portion between the substrate and the surface mount part.

FIG. 4 illustrates the state of the solder material in the bonding portion.

FIG. 5 is an enlarged photograph of a solder alloy according to a reference example.

FIG. 6(a) to FIG. 6(c) dynamically illustrate the state of the solder in the electronic part when a reflow process is performed by using a conventional solder.

### DESCRIPTION OF EMBODIMENTS

The solder material of the invention is elaborated in the following embodiments. According to this embodiment, the solder material is a cream solder material (a soldering paste) which includes first solder powder, second solder powder, Cu powder coated by Ag, and a flux mixed with the first solder powder, the second solder powder, and the Cu powder. The first solder powder contains Cu, Si, Ti, and Sn. Here, Cu accounts for 7 wt %˜9 wt %, Si accounts for 0.001 wt %˜0.05 wt %, Ti accounts for 0.001 wt %˜0.05 wt %, and the rest is Sn. The second solder powder contains Ag, Cu, and Sn. Here, Ag accounts for 2.9 wt %˜3.1 wt %, Cu accounts for 0.4 wt %˜0.6 wt %, and the rest is Sn.

In a solder alloy that constitutes the first solder powder, when Cu accounts for less than 7 wt %, the solidus temperature is not sufficient in comparison with the Sn-3.0Ag-0.5Cu solder that is frequently used for packaging the electronic part in the machine. On the contrary, when Cu accounts for more than 9 wt %, the liquidus temperature is raised. Therefore, when the solder powder is formed by applying an atomization method described hereinafter, the heating performance of the heating furnace or the heat resistance needs to be improved, which may lead to an increase in the manufacturing costs. Accordingly, Cu in the first solder powder preferably accounts for 7 wt %˜9 wt %, more preferably accounts for 8 wt %.

Besides, when a trace of Si added to the first solder powder is less than 0.001 wt %, the flowability of the solder material is insufficient during the soldering process. By contrast, when Si is more than 0.05 wt %, the tensile strength of the solder alloy is reduced, or dross (oxide) is likely to be generated. Moreover, when Ti is less than 0.001 wt %, the mechanical strength, the heat resistance, or the corrosion resistance of the solder alloy cannot be increased sufficiently. By contrast, when Ti is more than 0.05 wt %, dross (oxide) is very much likely to be generated.

Given only one of Si and Ti is added to the first solder powder, the disadvantages of each element emerge. However, by adding both Si and Ti to the first solder powder, Si and Ti can develop the merits and compensate the demerits. As such, the solder material that is suitable for performing a soldering process, has favorable mechanical strength, and is characterized by high heat resistance and high corrosion resistance can be obtained.

Based on the above, the first solder powder preferably contains the following composition: Cu accounts for 7 wt %˜9 wt %, Si accounts for 0.001 wt %˜0.05 wt %, Ti accounts for 0.001 wt %˜0.05 wt %, and the rest is Sn. More preferably, the first solder powder, for example, is the Sn-8.0Cu-0.025Si-0.025Ti solder alloy in which Cu accounts for 8.0 wt %, Si accounts for 0.025 wt %, Ti accounts for 0.025 wt %, and the rest is Sn. Here, the first solder powder can also include impurities that conform to the JIS-Z3282 standard.

The second solder powder preferably contains the following composition: Ag accounts for 2.9 wt %˜3.1 wt %, Cu accounts for 0.4 wt %˜0.6 wt %, and the rest is Sn. More preferably, the second solder powder, for instance, is the Sn-3.0Ag-0.5Cu solder which is extensively applied as a non-lead solder. Here, the second solder powder can also include impurities that conform to the JIS-Z3282 standard.

The first solder powder, preferably the Sn-8.0Cu-0.025Si-0.025Ti solder, has a solidus temperature of approximately 235° C. and a liquidus temperature of approximately 288° C. The second solder powder, preferably the Sn-3.0Ag-0.5Cu solder, has a solidus temperature of approximately 217° C. and a liquidus temperature of approximately 220° C. Therefore, the temperature at which the second solder powder starts to melt is lower than the temperature at which the first solder powder starts to melt, which may induce the first solder powder to melt or increase the wettability of the entire solder material.

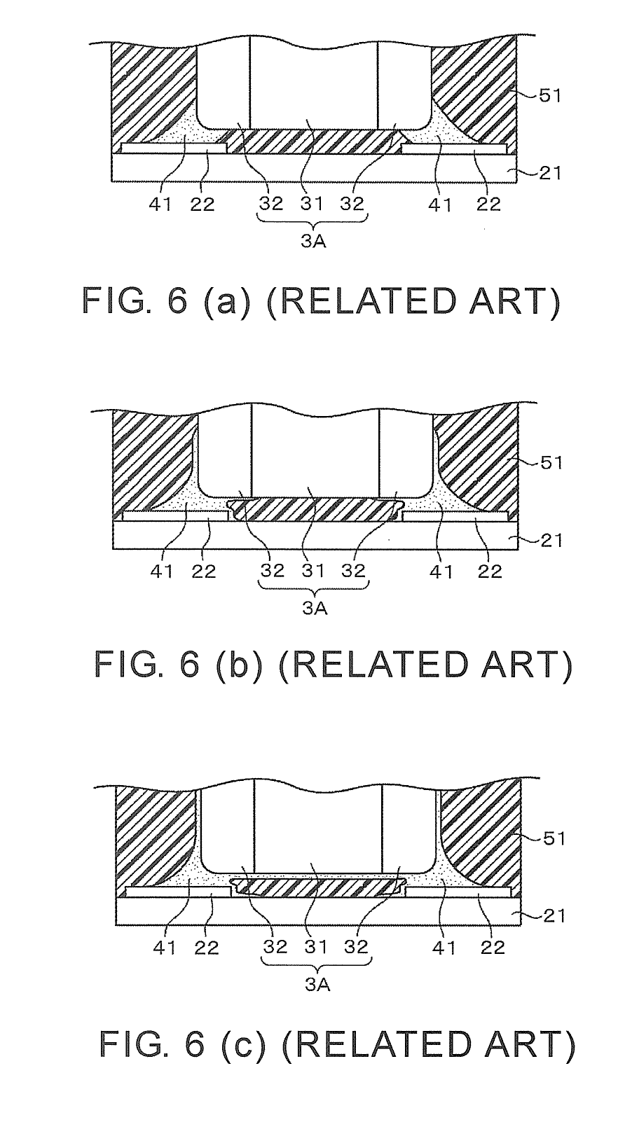

After the soldering process is performed, the metal constituting the first solder material and the metal constituting the second solder material are mixed to form the solder alloy having the new composition. This solder alloy has a solidus temperature which is expected to range between the solidus temperature of the first solder material and the solidus temperature of the second solder material, and thus the solder alloy cannot be easily melted in comparison with the second solder material. The second solder powder, preferably the Sn-3.0Ag-0.5Cu solder, is extensively applied as a non-lead solder. For instance, when the surface mount part of this embodiment is mounted by applying the solder material described in this embodiment and forms the electronic part, the electronic part is very much likely to be packaged in the machine by applying the Sn-3.0Ag-0.5Cu solder. Under said circumstances, the solder alloy in the electronic part has a higher solidus than that of the Sn-3.0Ag-0.5Cu solder, so as to prevent the solder alloy in the electronic part from being melted again and prevent breakdowns to the surface mount part because of short circuit described in the related art with reference to FIG. 6(a) to FIG. 6(c).

A method of forming the first solder powder and the second solder powder, for instance, includes gas atomization, centrifugal atomization, pulverization, and so on. In the gas atomization method, metal that serves as a raw material of the solder powder is melted in a heated crucible, and a spray process is performed in an airstream such as nitrogen gas. In the centrifugal atomization method, the melted metal is continuously supplied to a turntable rotated at a high speed and is sprayed to the periphery of the turntable due to a centrifugal force. In the pulverization method, the well-known pulverizer including a turbo mill, a roll mill, a metal powder pulverizer, and a centrifugal pulverizer is applied.

The particle size of the solder powder is preferably an equivalent spherical diameter obtained by a well-known particle size distribution (PSD) method, such as particle imaging, zeta (ζ) potential measurement, and so on. The average particle size of the solder powder ranges from about 5 μm to about 50 μm, preferably from about 5 μm to about 30 μm. If the particles are overly large, the printability of the soldering paste on the substrate is reduced; if the particles are excessively small, the wettability of the solder material is reduced when the soldering paste is heated. In order to well disperse the solder powder in the solder material, particles of each solder powder are preferably in a spherical shape or substantially in a spherical. Alternatively, the particles of the solder powder can have uneven surfaces. In addition, the particle size can be determined by not only applying the afore-mentioned method but also conducting an electric sensing zone analysis, a laser diffraction technology, or a chemical absorption method. According to the electric sensing zone analysis or the laser diffraction technology, the PSD is determined. In the chemical absorption method, the specific surface area of the particles can be measured, or pore size distribution can be analyzed.

The solder material of this embodiment includes the Cu powder which has a melting temperature much higher than the melting temperature of the first solder powder and the melting temperature of the second solder powder. Note that the melting temperature of Cu is 1083° C. As such, the Cu powder is not melted during the soldering process for mounting the surface mount part or mounting the electronic part having the surface mount part. Even of the solder material is melted, the Cu powder still exists in a solid state in the melted solder material, so as to restrain the volume expansion of the entire solder material.

Besides, the Cu powder is coated by Ag, for instance. Thereby, in the soldering process for mounting the surface mount part, a small amount of Ag coated onto the Cu powder is dissolved in the solder material due to the metal expansion occurring at the interface between Ag and the solder material. Similarly, a small amount of Cu which underlies Ag is also dissolved in the solder material, such that the liquidus temperature of the solder alloy is raised after the soldering process is performed. As long as the liquidus temperature of the solder alloy is increased, the solder alloy in the electronic part cannot be easily melted. Even if the solder alloy is melted, a mixture of the solder material in the liquid state and the solder material in the solid state can be between the solidus and the liquidus, such that the proportion of the liquid in the sherbet-like solder material can be reduced, and that the volume expansion can be restrained.

Ag coated onto the Cu powder is the same as Ag included in the second solder powder and can improve affinity (compatibility) to the solder material and the Cu powder. Moreover, Ag allows the Cu powder to be dispersed in the solder material to a better extent. Accordingly, the occurrence of the discontinous points in the solder alloy can be inhibited after the soldering process is performed. Even if the Cu powder is added to the solder material, the soldering properties of the solder material are not compromised. Here, “affinity is high” refers to the formation of inter-metallic compound between the solder alloy after the soldering process is performed. More specifically, it means the Cu powder is almost not aggregated at all and is well dispersed in the solder alloy.

The Cu powder can be made by gas atomization, water atomization, or pulverization with use of a pulverizer. The particle size of the Cu powder coated by Ag is substantially the same as the particle size of the aforesaid solder powder, for instance. Based on the result obtained by particle imaging, for instance, the average particle size of the Cu powder ranges from about 5 μm to about 50 μm, preferably from about 5 μm to about 30 μm. In order to well disperse the Cu powder in the solder material, the Cu powder is preferably in a spherical shape or substantially in a spherical shape before Ag is coated onto the Cu powder. Alternatively, the Cu powder can have an uneven surface.

In order to simply coat the Cu powder with Ag having almost the same thickness, Ag is preferably coated onto the Cu powder by performing an electroplating process. The electroplating process can be an electrolytic electroplating process, a non-electrolytic electroplating process, or any other well-known electroplating process. However, the Ag metal film can also be formed by performing a process other than the electroplating process.

The amount of Ag coated onto the Cu powder is not specifically limited in the invention as long as the technical effects of the Cu powder are not compromised. Wherein the technical effects of adding Cu powder are restraining the volume expansion of the melted solder alloy and improving the affinity to the solder material. The weight of Ag preferably accounts for 5 wt %˜20 wt % of the total weight of the Cu powder coated with Ag. More preferably, the weight of Ag accounts or 8 wt %˜12 wt % of the total weight of the Cu powder coated with Ag.

Besides, the Cu powder preferably accounts for 10 wt %˜35 wt % of the total weight of the first solder powder, the second solder powder, and the Cu powder. If the Cu powder added to the solder material is excessive, the proportion of other solder components in the solder material is lowered down, and thus the solder material cannot be fully functioned. On the contrary, if the Cu powder added to the solder material is insufficient, the volume expansion of the melted solder material cannot be well restrained, or the liquidus temperature is not raised after Ag or Cu is dissolved in the solder alloy.

The second solder powder preferably accounts for 0.1 wt %˜60 wt % of the total weight of the first solder powder, the second solder powder, and the Cu powder. If the second solder powder added to the solder material is excessive, the proportion of the first solder powder is lowered down, the solidus temperature is reduced, and thus the solder alloy in the electronic part is apt to be melted again. If the second solder powder added to the solder material is insufficient, the wettability of the entire solder material cannot be improved, or the first solder powder is less apt to be melted.

A flux mixed with the first solder powder, the second solder powder, and the Cu powder to form the solder material is described hereinafter. The flux of this embodiment can be a well-known flux mixed by polymer materials, such as amine halide salts, polyalcohol, rosin, and so on. In this embodiment, the flux is mixed with the solder powder and the Cu powder, so as to form the cream flux. Besides, the flux can be applied regardless of the level of activation. However, in consideration of removing the flux after the soldering process is performed, the flux is preferably a water-soluble flux that can be water-rinsed. The flux, for instance, accounts for approximately 5 wt %˜20 wt % of the total weight of the solder material.

The cream solder material described above can be formed by mixing the first solder powder, the second solder powder, the Cu powder, and the flux. The mixing process can be performed by employing a well-known machine including a Banbury mixer, a kneader, and so on. However, if the first solder powder or the second solder powder in the solder material is aggregated, the soldering process cannot be performed with ease, or the portions easily melted after the soldering process are arranged in a dotted manner. Moreover, if the Cu powder is aggregated, the portion cannot be well mounted during a heating process are arranged in a dotted manner. Hence, the Cu powder is evenly dispersed according to a preferred embodiment.

Given the viscosity of the finished cream solder material is overly high, the solder material may blur when the solder material is printed on the substrate. By contrast, given the viscosity of the finished cream solder material is insufficient, the solder material may drip on the substrate or run over the substrate when the solder material is printed on the substrate. Hence, the viscosity of the cream solder material at the temperature of 25° C. preferably ranges from about 100 Pa·S to about 300 Pa·S, more preferably ranges from about 190 Pa·S to about 220 Pa·S.

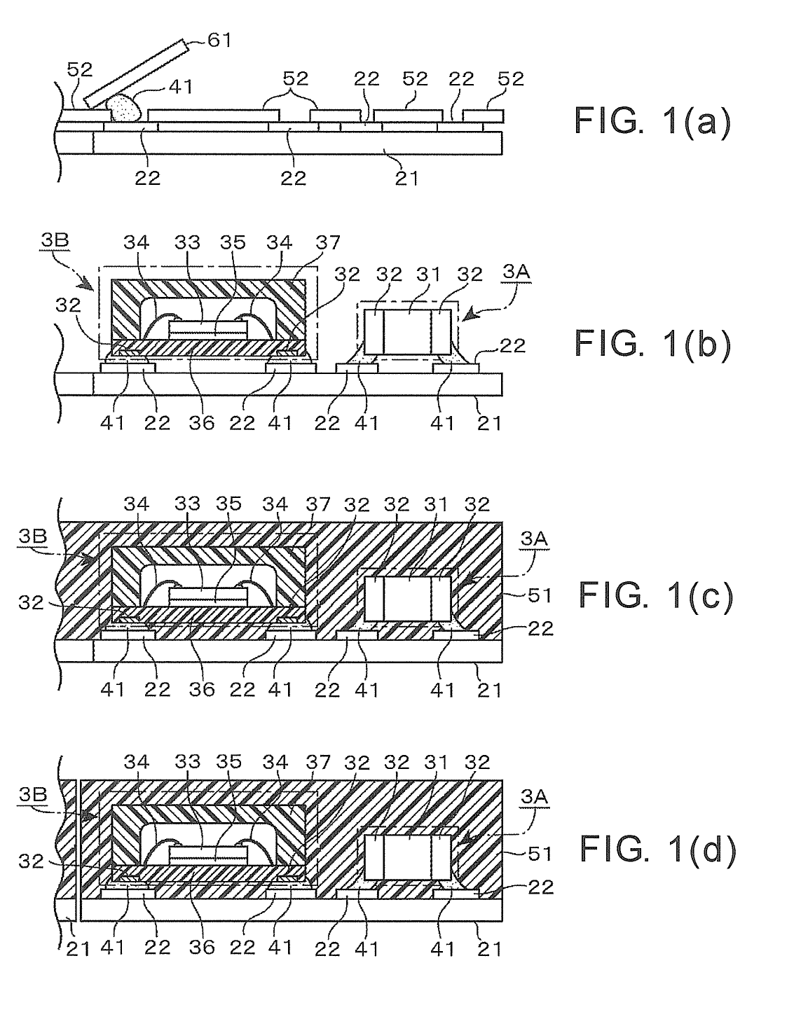

The fabrication of the electronic part with use of the solder material (the soldering paste) 41 which contains the first solder powder (e.g., Sn-8.0Cu-0.025Si-0.025Ti), the second solder powder (e.g., Sn-3.0Ag-0.5Cu), and the Cu powder coated with Ag is described in the following embodiment with reference to FIG. 1(a) to FIG. 1(d).

The method of manufacturing the electronic part can be applied to package a plurality of surface mount parts in an individual electronic part. To simplify the description of the method, two surface mount parts 3A and 3B are exemplarily packaged in each electronic part in the following description. Here, the surface mount part 3A has electrodes 32, a SAW chip 33, bonding wires 34, a supporting board 35 that supports the SAW chip 33, an interpolator 36, and a covering component 37. The surface mount part 3B has a chip part 31 and electrodes 32.

As shown in FIG. 1(a), metal masks 52 having openings aligned to installation pads 22 that serve as the electrodes are configured on a substrate 21. The solder material 41 is supplied to the substrate 21 by a solder printer. Meanwhile, the solder material 41 is spread by a wiper 61 and coated onto the substrate 21 through the openings of the metal masks 52.

As a result, the solder material 41 whose shape is compliant with the shape of the installation pads 22 is printed on the substrate 21. Besides, the solder material 41 can be supplied in dispensing ways. However, from a perspective of production efficiency, the solder material 41 is preferably printed on the substrate 21 in the way described above. The solder printer of this embodiment can be any conventional solder printer.

The metal masks 52 are removed from the surface of the substrate 21, and the surface mount parts 3A and 3B are placed at predetermined locations on the substrate 21 by physically connecting the electrodes 32 of each of the surface mount parts 3A and 3B to the solder material 41.

The substrate 21 on which the surface mount parts 3A and 3B are configured is moved into a reflow furnace, and a heating process is performed. The reflow process can be an infrared reflow process, an N₂ reflow process, and so on. In the infrared reflow process, an infrared heater serves as a heating source. In the N₂ reflow process, the heating operation is carried out in the N₂ environment. By performing the preferable N₂ reflow process, the surface temperature of the surface mount parts can be lowered down, and the wettability of the solder material can be further improved. The partial pressure of oxygen in the reflow furnace is preferably at 100 ppm or lower.

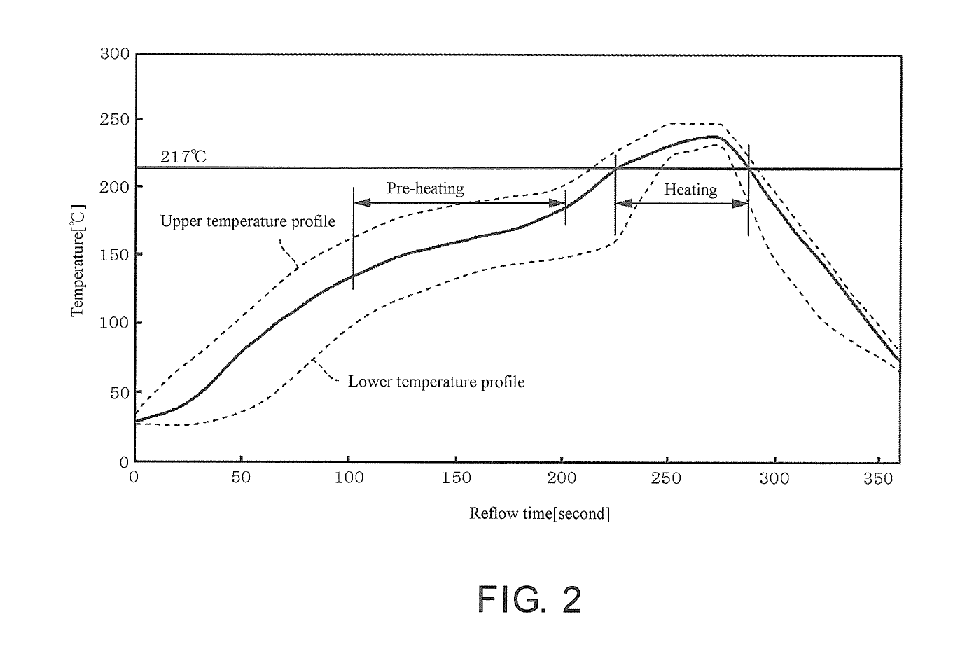

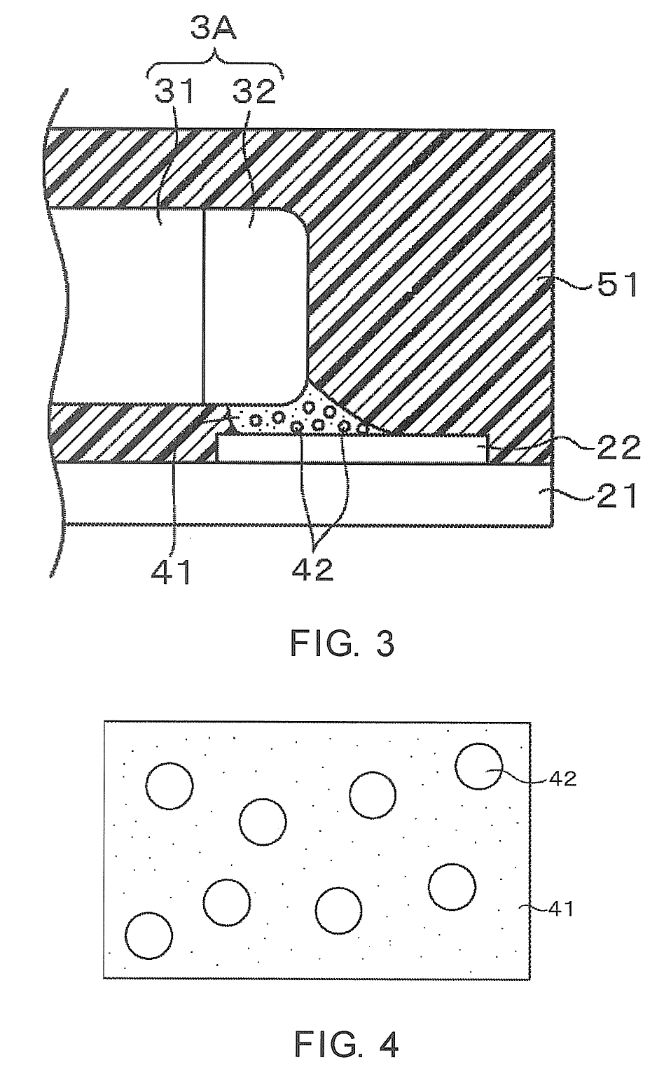

FIG. 2 illustrates exemplary distribution of temperature that is changed with time when the electronic part is moved into the reflow furnace. In FIG. 2, the horizontal axis represents time [second] at which the heating process starts to be performed, and the vertical axis denotes the temperature [° C.] in the reflow furnace. The temperature distribution illustrated by dotted lines represents the upper limit (upper temperature profile) and the lower limit (lower temperature profile) of the adjustable temperature, and the temperature distribution illustrated by solid lines represents the range of the adjustable temperature. As shown by the solid lines, the temperature in the reflow furnace is raised to about 130° C., for instance, and the temperature is further raised to about 190° C. after 60 seconds ˜90 seconds approximately. During this period, the solder material 41 is pre-heated, the solvent (e.g., polyalcohol) in the flux is evaporated, and the flux is activated.

After the pre-heating process is completely performed, the temperature in the reflow furnace is increased to be at 217° C. or more, which exceeds the solidus temperature of the second solder powder, so as to perform the heating process. When the temperature in the reflow furnace exceeds 217° C., the second solder powder starts to melt, and the solder material 41 at the surfaces of the installation pads 22 or the surface of the Cu powder starts to be wet. Here, Ag coated onto the Cu powder or Cu that underlies Ag starts to be dissolved in the solder material 41.

The temperature in the reflow furnace is further raised. After the temperature in the reflow furnace exceeds 235° C., the first solder powder starts to melt, and the first solder powder, the second solder powder, and the dissolved Ag or the dissolved Cu in the Cu powder are mixed together, so as to form the solder alloy containing Sn, Cu, Ag, Si, and Ti. The heating process is performed at 235° C.˜240° C. for about 60 seconds, for instance. The difference between the temperature at which the heating process is performed and the melting temperature (217° C.˜218° C.) of the Sn-3.0Ag-0.5Cu solder that serves as a common non-leaded solder is 20° C. or less, and thus the temperature difference does not make a great impact on the surface mount parts. Within said temperature range, the Cu powder is in the solid state and is dispersed in the solder alloy.

If the reflow furnace is cooled down, the solder alloy is cured, the electrodes 32 located at the sides of the surface mount parts 3A and 3B are fixed to the installation pads 22 located on the substrate 21, and the parts 3A, 3B and 22 are electrically connected. As such, the surface mount parts 3A and 3B are packaged on the substrate 21, as indicated in FIG. 1(b).

After the process of packaging the surface mount parts 3A and 3B is completely carried out, the substrate is moved from the reflow furnace, and the flux attached to the solder material 41 and each electronic part is water-rinsed and removed.

A sealing material 51 is supplied to the substrate 21 after the flux is removed. Specifically, each of the surface mount parts 3A and 3B on the substrate 21 is covered by the sealing material 51, and the sealing material 51 is solidified, so as to seal each of the surface mount parts 3A and 3B on the substrate 21, as indicated in FIG. 1(c). The sealing material 51 can be supplied by a dispenser, a printer, and so on. Besides, the sealing material 51 can be solidified by employing a heating furnace. Alternatively, the surface mount parts on the substrate 21 can be covered by a mold, the sealing material 51 in a liquid form is pressed into the mold, and the mold is then heated, so as to solidify the sealing material 51.

As indicated in FIG. 1(d), after the sealing material 51 is solidified, the sealing material 51 and a portion of the substrate 21 on which the surface mount parts 3A and 3B are formed are cut off, so as to form the electronic part. Note that the electronic part not only can have plural surface mount parts but also can have a single surface mount part, which still falls within the scope of the invention.

In the method of fabricating the electronic part, the surface mount parts 3A and 3B are packaged on one surface of the substrate 21. However, in another embodiment of the invention, it is likely to package the surface mount parts on both surfaces of the substrate 21. For instance, after the surface mount parts 3A and 3B are packaged on one surface of the substrate 21 by performing the steps described in the previous embodiment, the same steps can be implemented to package other surface mount parts on the other surface of the substrate 21. When the surface mount parts are packaged on both surfaces of the substrate 21, the water-rinse step for removing the flux is not performed right after the step of packaging the surface mount parts on one surface of the substrate 21 but performed after the surface mount parts are packaged on both surfaces of the substrate 21.

FIG. 3 is an enlarged view of a bonding portion between the installation pads 22 and the electrodes 32 of the surface mount part 3A. Meanwhile, FIG. 3 schematically shows that the Cu powder 42 is dispersed in the solder material 41. FIG. 4 illustrates the state of the Cu powder 42 in the solder material 41. In the electronic part, the solder alloy 41 is formed by melting the first solder powder and the second solder powder and dissolving Ag or Cu of the Cu powder 42, and the Cu powder 42 is dispersed in the solder alloy 41 to form the solder material. Thereby the electrodes 32 of each of the surface mount parts 3A and 3B are electrically connected to the installation pads 22 on the substrate 21.

When the electronic part is packaged in a machine, e.g., a mobile phone, the common Sn-3.0Ag-0.5Cu solder is applied as a non-leaded solder, and the electronic part is heated in the reflow furnace until the temperature reaches approximately 217° C.˜245° C. At this time, the first solder powder and the second solder powder are melted, and Ag or Cu in the Cu powder is dissolved, so as to form the solder alloy 41. Since the melting temperature of the solder alloy 41 is higher than the melting temperature of the Sn-3.0Ag-0.5Cu solder, the solder alloy 41 cannot be easily melted within said temperature range.

Even if the solder alloy 41 is partially melted because the first solder powder and the second solder powder are not fully mixed or because the proportion of the first solder powder in the solder alloy 41 is insufficient, for instance, the Cu powder that is in the solid form and is dispersed in the melted solder alloy can restrain the volume expansion of the solder alloy. As a result, the solder material is less likely to be overflowed to the interface among the surface mount part 3A, the substrate 21, and the sealing material 51, such that the problem of short circuit between the electrodes 32 and the resulting breakdowns to the electronic part as described in the related art can be prevented. The same effects can be achieved even though the electronic part is removed from the wiring substrate for repairing the electronic product.

As indicated in FIG. 4, Ag coated onto the Cu powder is completely dissolved in the solder alloy 41, and the Cu powder 42 constituted by Cu is exposed. Alternatively, the Cu powder 42 can still be coated by Ag. Even if Ag coated onto the Cu powder 42 is partially dissolved, the liquidus temperature of the solder alloy can still be increased.

In the first solder powder of the solder material described in this embodiment, Cu accounts for 7 wt %˜9 wt %, Si accounts for 0.001 wt %˜0.05 wt %, Ti accounts for 0.001 wt %˜0.05 wt %, and the rest is Sn. The solder material of this embodiment starts to melt at approximately 235° C. The surface mount parts are packaged by applying the solder material containing the first solder powder and are sealed to form an electronic part. Therefore, even though the frequently used Sn-3.0Ag-0.5Cu solder having a solidus temperature at about 217° C. is applied to package said electronic part in the machine, the solder material in the electronic part cannot be easily melted. Since the solder material is not apt to be melted, the breakdowns to the electronic part caused by volume expansion of the solder material are less likely to occur.

Besides, by adding a trace of Si and a trace of Ti to the first solder powder, the solder material containing the first solder powder can have favorable mechanical properties, high heat resistance, and high corrosion resistance.

Further, the second solder powder added to the first solder powder starts to melt earlier than the first solder powder, and thereby the wettability of the entire solder material can be improved, or the first solder powder can be induced to melt.

In addition to the above, the Cu powder coated by Ag is added to the solder material. As such, even if the solder alloy used for packaging the surface mount parts starts to melt when the electronic part is packaged on the electronic machine, the Cu powder that is in a solid form and is dispersed in the melted solder alloy can restrain the volume expansion of the melted solder alloy. Note that the Cu powder is coated by Ag. Hence, Ag or Cu that underlies Ag is dissolved in the solder alloy when the soldering process is performed on the surface mount parts, and thereby the liquidus temperature of the solder alloy is increased and the proportion of melted solder is reduced, so as to restrain the volume expansion.

In the previous embodiments, the cream solder material in which the first solder powder, the second solder powder, the Cu powder, and the flux are mixed is elaborated, while the solder material excluding the second solder powder also falls within the technical scope of the invention.

Given the cream solder material contains the first solder powder, the Cu powder coated by Ag, and the flux that are mixed together, the solder material is hard to melt in comparison with the frequently used Sn-3.0Ag-0.5Cu solder. Even if the cream solder material is melted, the Cu powder or the dissolved Ag can also restrain the volume expansion. Under said circumstances, the Cu powder preferably accounts for 10 wt %˜35 wt % of the total weight of the first solder powder and the Cu powder, and the rest is the first solder powder.

When the solder material (e.g., a solder wire or a solder foil) in which Cu accounts for 7 wt %˜9 wt %, Si accounts for 0.001 wt %˜0.05 wt %, Ti accounts for 0.001 wt %˜0.05 wt %, and the rest is Sn is provided, and the solder material is not a cream solder material and does not contain the Cu powder, the solder material is still hard to melt in comparison with the Sn-3.0Ag-0.5Cu solder. In this embodiment, the “solder composition” refers to an alloy that has the designated composition and can serve as a solder.

### EXAMPLES

### (Experiment 1)

In order to verify the effects achieved by adding a trace of Si and a trace of Ti to the solder alloy, a solder alloy containing a trace of Si and a trace of Ti, a solder alloy containing a trace of Si, and a solder alloy that contains neither Si nor Ti are employed in Experiment 1.

### A. Conditions of Experiment 1

A tensile experiment is conducted on the solder alloy exemplified in the following reference examples 1-3 to measure the tensile strength, the elongation at break, and the linear coefficient of expansion. The tensile experiment is conducted based on the method that conforms to the JIS-Z3198-2 standard, and the tensile strength and the elongation at break are calculated by the following equation (1) and equation (2).

(Tensile Strength)

σ=Fₘₐₓ/A (1)

, wherein σ is the tensile strength (MPa=N/mm²),

Fₘₐₓ is the maximum tensile force (N), and

A is the cross-sectional area (mm²).

(Elongation at Break)

δ=(1−1₀)×100/1₀ (2)

, wherein 5 is the elongation at break (%),

1 is the length between two reference points (mm), and

1₀ is the distance between original reference points (mm).

The linear coefficient of expansion is determined when the temperature ranges from 0° C. to 100° C. and measured by the thermal coefficient calculator DSC-60 made by Shimadzu Corporation or the thermal coefficient calculator TMA/SS6000 made by Seiko Instruments.

### Reference Example 1

The solder alloy containing a trace of Ti and a trace of Si is employed herein for experiment.

Composition of Solder Alloy: 98.285Sn-1.0Ag-0.7Cu-0.01Si-0.005Ti

### Reference Example 2

The solder alloy containing a trace of Si but having no Ti is employed herein for experiment.

Composition of Solder Alloy: 98.29Sn-1.0Ag-0.7Cu-0.01 Si

### Reference Example 3

The solder alloy that does not contain Ti and Si is employed herein for experiment.

Composition of Solder Alloy: 98.3Sn-1.0Ag-0.7Cu

### B. Experimental Results

The tensile strength, the elongation at break, and the linear coefficient of expansion of the solder alloy in each reference example are shown in (Table 1). Each of the results is obtained by conducting the experiment on each solder alloy for 2-3 times and averaging the experimental results.

TABLE 1

| | Reference | Reference | Reference |
|---|---|---|---|
| | Example 1 | Example 2 | Example 3 |
| Tensile Strength[Mpa] | 30.1 | 30.3 | 30.6 |
| Elongation Rate[%] | 82.5 | 52.3 | 68.4 |
| Linear Coefficient of | 20.2 × 10⁻⁶ | 21.1 × 10⁻⁶ | 23.3 × 10⁻⁶ |
| Expansion (0° C.~100° C.) | | | |
| [mm] | | | |

In the tensile experiment (reference examples 1-3) as shown in (Table 1), the difference of tensile strength among the three reference examples 1-3 is not significant. The elongation rate in reference example 1 is approximately 1.2 times˜1.6 times the elongation rate in reference examples 2 and 3. Since the solder alloy that contains a trace of Ti and a trace of Si (reference example 1) has almost the same tensile strength as that of the solder alloy in reference examples 2 and 3 but has a greater elongation rate than that of the solder alloy in reference examples 2 and 3, the solder alloy in reference example 1 is characterized by high tenacity in comparison with the solder alloy in reference examples 2 and 3. Moreover, the linear coefficient of expansion of the solder alloy in reference example 1 is less than that of the solder alloy in reference examples 2 and 3. Therefore, the solder alloy in reference example 1 is hard to be expanded even though the solder alloy is in a solid state. Based on the above, when the solder alloy contains a trace of Ti, a trace of Si, and Sn as the main ingredient, the tenacity of the solder alloy can be improved, and the solder alloy is not apt to be expanded. Besides, based on the above results, the solder alloy having the first solder powder only and the solder alloy further including the second solder powder or the Cu powder coated by Ag can achieve the same effects. Namely, a trace of Ti and a trace of Si added to the solder material lead to the improvement of the solder alloy.

### (Experiment 2)

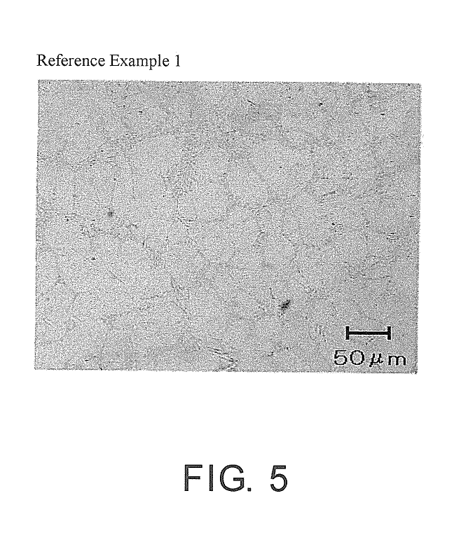

The solder alloy in reference example 1 is enlarged and observed by employing an optical microscope. The observation result is shown in FIG. 5.

As shown in the enlarged photograph of FIG. 5, there are no holes, gaps, or crystallized Cu in a needle shape in the solder alloy that has a trace of Si and a trace of Ti. As such, the polycrystalline alloy with high density and high corrosion resistance can be expected.

Although the present invention has been disclosed above by the embodiments, they are not intended to limit the invention. Anybody skilled in the art can make some modifications and alteration without departing from the spirit and scope of the invention. Therefore, the protection range of the invention falls in the appended claims.

What is claimed is:

1. A solder material, characterized in that the solder material comprises:
first solder powder, containing Cu, Si, Ti, and Sn, wherein Cu accounts for 7 wt %˜9 wt %, Si accounts for 0.001 wt %˜0.05 wt %, Ti accounts for 0.001 wt %˜0.05 wt %, and the rest is Sn;
Cu powder, coated by Ag; and
a flux, mixed with the first solder powder and the Cu powder.

2. The solder material as claimed in claim 1, wherein
the Cu powder accounts for 10 wt %˜35 wt % of the total weight of the first solder powder and the Cu powder, and the rest is the first solder powder.

3. The solder material as claimed in claim 1, further comprising second solder powder containing Ag, Cu, and Sn, wherein Ag accounts for 2.9 wt %˜3.1 wt %, Cu accounts for 0.4 wt %˜0.6 wt %, and the rest is Sn.

4. The solder material as claimed in claim 3, wherein
the Cu powder accounts for 10 wt %˜35 wt % of the total weight of the first solder powder, the second solder powder, and the Cu powder, the second solder powder accounts for 1.0 wt %˜60 wt % of the total weight of the first solder powder, the second solder powder, and the Cu powder, and the rest is the first solder powder.

5. A solder material, characterized in that the solder material comprises a solder composition containing Cu, Si, Ti, and Sn, wherein Cu accounts for 7 wt %˜9 wt %, Si accounts for 0.001 wt %˜0.05 wt %, Ti accounts for 0.001 wt %˜0.05 wt %, and the rest is Sn.

6. An electronic part, characterized in that:
a surface mount part is packaged on a wiring substrate by applying the solder material as claimed in claim 1.

7. An electronic part, characterized in that:
a surface mount part is packaged on a wiring substrate by applying the solder material as claimed in claim 1 and is sealed by applying a sealing material to form the electronic part.

8. A method of fabricating an electronic part, characterized in that the method comprises following steps:
providing electrodes of a wiring substrate with the solder material as claimed in claim 1;
placing a surface mount part on the solder material;
electrically connecting electrodes of the surface mount part to the electrodes of the wiring substrate by heating and melting the solder material; and
sealing the surface mount part by applying a sealing material.

9. An electronic part, characterized in that:
a surface mount part is packaged on a wiring substrate by applying the solder material as claimed in claim 5.

10. An electronic part, characterized in that:
a surface mount part is packaged on a wiring substrate by applying the solder material as claimed in claim 5 and is sealed by applying a sealing material to form the electronic part.

11. A method of fabricating an electronic part, characterized in that the method comprises following steps:
providing electrodes of a wiring substrate with the solder material as claimed in claim 5;
placing a surface mount part on the solder material;
electrically connecting electrodes of the surface mount part to the electrodes of the wiring substrate by heating and melting the solder material; and
sealing the surface mount part by applying a sealing material.
